(19) United States
(12) Patent Application Publication
(10) Pub. No.: US 2008/0290340 A1
(43) Pub. Date: Nov. 27, 2008

(54) Method for fabricating a semiconductor device having embedded interconnect structures to improve die corner robustness

(75) Inventor: Jeffrey Alan West, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/805,325

(22) Filed: May 23, 2007

(51) Int. Cl. H01L 23/48; H01L 21/4763

(52) U.S. Cl. 257/48; 438/618; 257/E21.495; 257/E29.005

(57) ABSTRACT

In a method for fabricating a semiconductor device a redundant scribe seal structure is formed. The semiconductor device includes a die having a rectangular shape with sloped corners. A scribe seal is formed to surround the die, the scribe seal having sides to form sloped corners that match the sloped corners of the die. A scribe seal extension having sharp corners is formed by extending the sides of the scribe seal that have a perpendicular orientation towards one another. The scribe seal extension redundantly encloses a corresponding one of the sloped corners of the scribe seal.

### BACKGROUND

The present invention is related in general to the field of semiconductor device assembly and packaging, and more specifically to fabricating integrated circuit (IC) devices that are protected against potential damage caused by stress induced defects such as cracks and delamination.

It is well known to use a scribe seal (may also be referred to as an edge seal, a die seal, or a seal ring) to protect a die against potential damage caused by stress induced defects such as crack formation and delamination formed during processes such as sawing, wirebonding, soldering, or during rigorous environmental testing. The scribe seal, which is typically formed around a perimeter of the die, is disposed between the die and a saw street (may also be referred to as a scribe street or a dicing street).

It is well known that stress induced defects such as cracks and delamination are likely to occur near the die corners where the induced stress is the highest. Conventional techniques to reduce damage caused by stress include providing a die layout having a sloped corner area rather than a die layout having a sharp corner, e.g., a 90 degree corner, and providing redundant scribe seals for added protection. However, conventional techniques may still be inadequate to protect the die corners, which are formed during the sawing. Low-k dielectric layers commonly used in the back end of line (BEOL) stack are susceptible to fracture during the sawing process and blisters or delamination due to mechanical stresses from subsequent packaging, moisture absorption, or thermal cycling. The fracture is likely to occur at the die corners thereby potentially leading to a rupture of the scribe seal(s) and potentially causing the die to fail.

### SUMMARY

Applicant recognizes an existing need for a method for fabricating a semiconductor device which provides improved protection against potential damage caused by stress induced defects, especially defects formed at or near the die corners, absent the disadvantages found in the prior techniques discussed above.

The foregoing need is addressed by the teachings of the present disclosure, which relates to a method for assembly and packaging of semiconductor devices. According to one embodiment, in a method for fabricating a semiconductor device a redundant scribe seal structure is formed. The semiconductor device includes a die having a rectangular shape with sloped corners. A scribe seal is formed to surround the die, the scribe seal having sides to form sloped corners that match the sloped corners of the die. A scribe seal extension having sharp corners is formed by extending the sides of the scribe seal that have a perpendicular orientation towards one another. The scribe seal extension redundantly encloses a corresponding one of the sloped corners of the scribe seal.

Several advantages are achieved by the method according to the illustrative embodiments presented herein. The embodiments advantageously provide an improved scribe seal structure that extends scribe seal protection close to the physical die corners. The improved scribe seal structure includes multiple metal walls which act as protective barriers against potential damage caused by stress induced defects, especially defects that originate at or near the physical corners of the die. The scribe seal structure is advantageously extended very close to the physical corners, where the induced stress is the highest. This limits the length of the cracks, and hence limits the leverage action of the stress forces before they encounter a metal wall. The semiconductor device having the improved scribe seal structure is advantageously manufacturable by using existing materials and processes, thereby improving reliability and reducing costs. The die size is unaffected by the improved scribe seal structure. That is, the redundant seal structure provides improved protection without increasing the die size.

### BRIEF DESCRIPTION OF THE DRAWINGS

FIG. 1A illustrates a simplified and schematic top view of a semiconductor device having an improved scribe seal extension, according to an embodiment;

FIG. 1B illustrates a simplified and schematic top view of a semiconductor device described with reference to FIG. 1A having an optional enclosed scribe seal, according to an embodiment;

FIG. 1C illustrates a simplified and schematic cross sectional view of a semiconductor device described with reference to FIG. 1B having an enclosed scribe seal, according to an embodiment;

FIG. 1D illustrates a simplified and schematic cross sectional view of a semiconductor device having a detached scribe seal, according to an embodiment; and

FIG. 2 is a flow chart illustrating a method for fabricating a semiconductor device having an improved scribe seal structure, according to an embodiment.

### DETAILED DESCRIPTION

Novel features believed characteristic of the present disclosure are set forth in the appended claims. The disclosure itself, however, as well as a preferred mode of use, various objectives and advantages thereof, will best be understood by reference to the following detailed description of an illustrative embodiment when read in conjunction with the accompanying drawings. The functionality of various circuits, devices or components described herein may be implemented as hardware (including discrete components, integrated circuits and systems-on-a-chip ‘SoC’), firmware (including application specific integrated circuits and programmable chips) and/or software or a combination thereof, depending on the application requirements.

Similarly, the functionality of various mechanical elements, members, or components for forming modules, sub-assemblies and assemblies assembled in accordance with a structure for an apparatus may be implemented using various materials and coupling techniques, depending on the application requirements. Descriptive and directional terms used in the written description such as top, bottom, left, right, and similar others, refer to the drawings themselves as laid out on the paper and not to physical limitations of the disclosure unless specifically noted. The accompanying drawings may not to be drawn to scale and some features of embodiments shown and described herein may be simplified or exaggerated for illustrating the principles, features, and advantages of the disclosure.

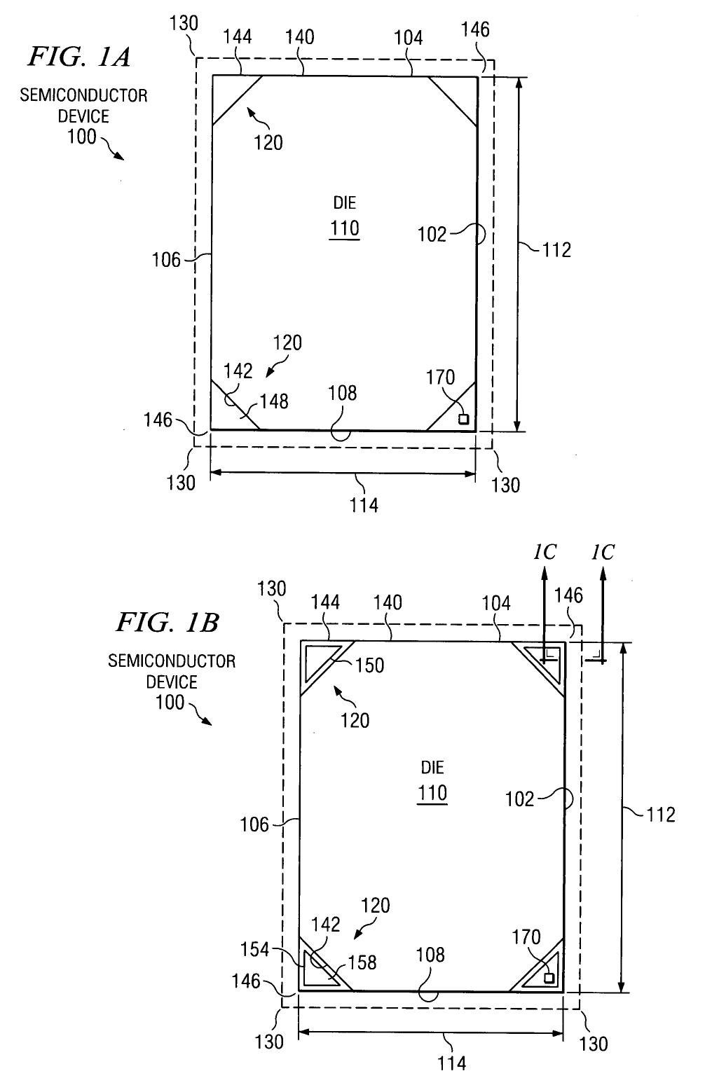

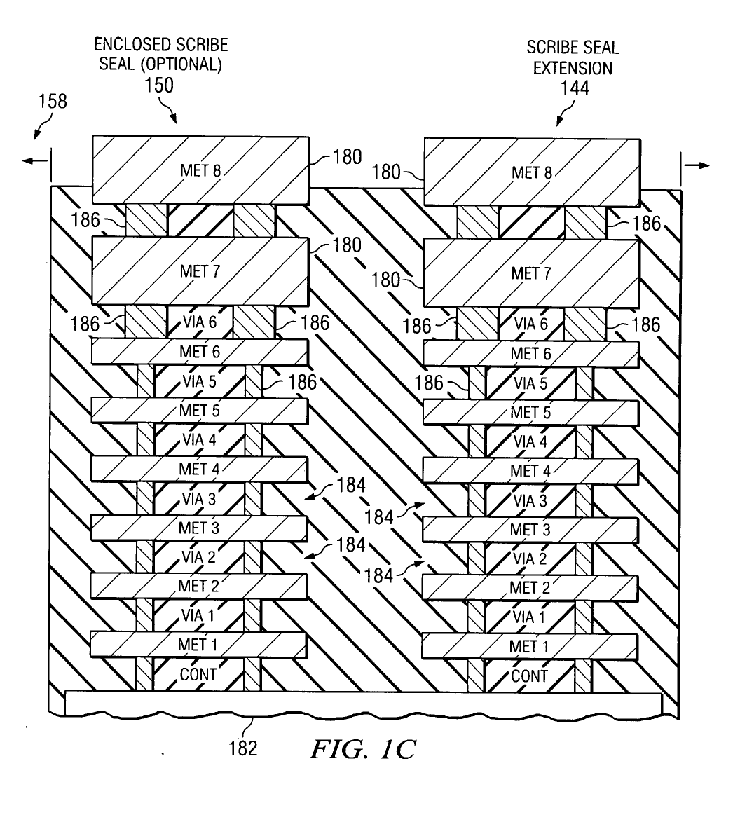

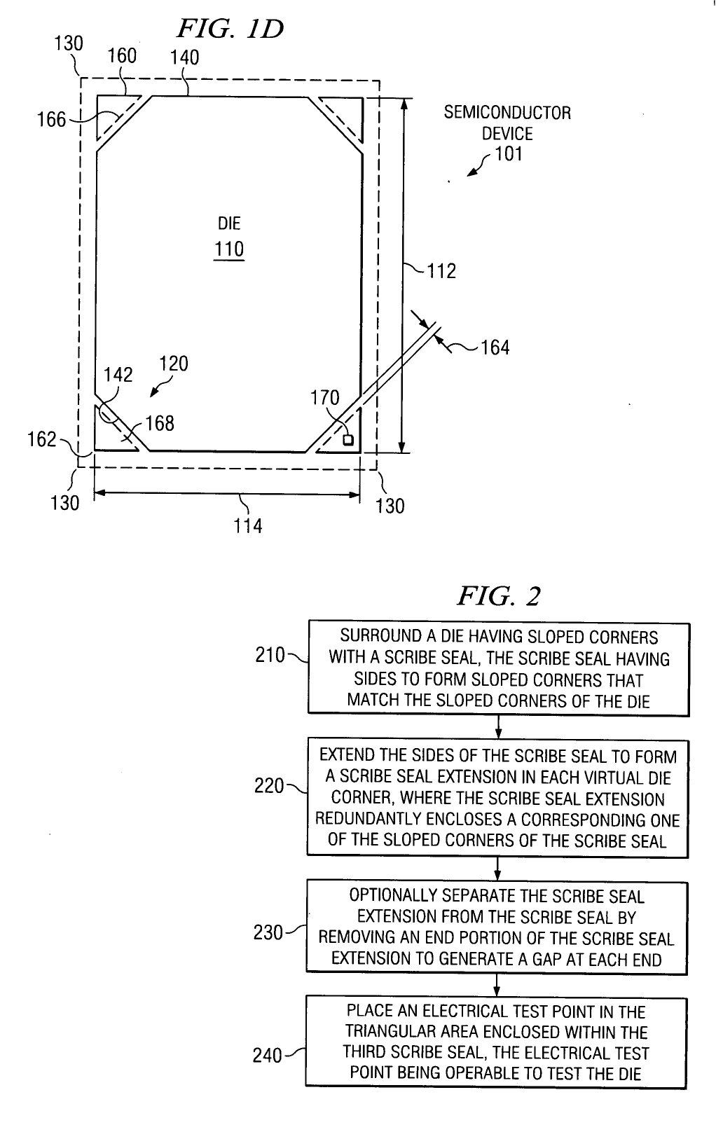

Formation of stress induced defects such as cracks and delamination are likely to occur near the die corners where the induced stress is the highest. Traditional tools and methods for fabricating a semiconductor device typically use a die layout having a sloped corner area rather than a die layout having a sharp corner to reduce the stress in the die corners. Use of redundant scribe seals also improves the protection. However, conventional techniques may still be inadequate to protect the die corners, which are formed during the sawing. Blistering or delamination of low-k dielectric layers may still occur at the die corners during the high stress processes, thereby potentially leading to a rupture of the scribe seal(s) and potentially causing damage to the die. This problem may be addressed by a method for fabricating a semiconductor device having an improved scribe seal structure with multiple metal walls. According to an embodiment, in a method for fabricating a semiconductor device a redundant scribe seal structure is formed. The semiconductor device includes a die having a rectangular shape with sloped corners. A scribe seal is formed to surround the die, the scribe seal having sides to form sloped corners that match the sloped corners of the die. A scribe seal extension having sharp corners is formed by extending the sides of the scribe seal that have a perpendicular orientation towards one another to form the sharp corners. The scribe seal extension redundantly encloses a corresponding one of the sloped corners of the scribe seal. The semiconductor device having an improved scribe seal structure and layout is described with reference to FIGS. 1A, 1B, 1C, 1D, and FIG. 2.

The following terminology may be useful in understanding the present disclosure. It is to be understood that the terminology described herein is for the purpose of description and should not be regarded as limiting.

Semiconductor Package (or Package)—A semiconductor package provides the physical and electrical interface to at least one integrated circuit (IC) or die for connecting the IC to external circuits. The package protects the IC from damage, contamination, and stress that result from factors such as handling, heating, and cooling. The process of putting the IC inside a package to make it reliable and convenient to use is known as semiconductor package assembly, or simply ‘assembly’.

Substrate—A substrate is an underlying material used to fabricate a semiconductor device. In addition to providing base support, substrates are also used to provide electrical interconnections between the IC chip and external circuits.

Semiconductor Device—A semiconductor device is an electronic component that utilizes electronic properties of semiconductor materials to perform a desired function. A semiconductor device may be manufactured as a single discrete device or as one or more ICs packaged into a module.

Scribe Seal—A scribe seal is a metal structure, which consists of a plurality of metal layers connected by vias. The scribe seal forms a wall of metal to protect the die against potential damage. The scribe seal thus provides a physical buffer area that allows for the dissipation of energy or stress induced during processes such as sawing, wirebonding, soldering, or during rigorous environmental testing. The scribe seal also provides a protective barrier for the die against infiltration by contaminants such as moisture and chemical impurities, which may be generated during processes such as sawing and soldering. A scribe seal is fabricated in the same manner as the back end of line (BEOL) stack of a semiconductor device.

Configuration—Describes a set up of an element, a circuit, a package, an electronic device, and similar other, and refers to a process for setting, defining, or selecting particular properties, parameters, or attributes of the device prior to or during its use or operation. Some configuration attributes may be selected to have a default value. For example, a sloped corner of a die may be configured to have a 45 degree angle, and a sharp corner for the die may be configured to have a 90 degree angle.

FIG. 1A illustrates a simplified and schematic top view of a semiconductor device 100 having an improved scribe seal extension, according to an embodiment. The semiconductor device 100 includes a die 110 having a rectangular shape with sloped corners 120. The die 110 has a length 112 and a width 114. The sloped corners 120 may be configured to have a 45 degree angle relative to the sides, e.g., the length 112 and the width 114. The process of singulating a wafer (not shown) containing the die 110 creates four physical die corners 130 of the die 110. Thus, the physical die corners 130 are actually located outside the perimeter of the die 110 and the active semiconductor structures of the die 110 are located within the perimeter. Each one of the physical die corners 130 form a 90 degree angle. That is, the physical die corners 130 have edges that are respectively parallel to the length 112 and the width 114 of the die 110.

A scribe seal 140 is formed around the perimeter of the die 110, thereby surrounding it. The scribe seal 140 includes sides to form sloped corners that match the sloped corners 120 of the die 110. The perimeter of the scribe seal 140 includes a first side 102 that is parallel to a third side 106, a second side 104 that is parallel to the fourth side 108, and four sloped corners 142 that are matched with the four sloped corners 120 of the die 110. In an exemplary, non-depicted embodiment, a redundant scribe seal may be formed between the scribe seal 140 and the die 110 for added protection. The sides of the scribe seal 140 that are oriented in a perpendicular direction to one another, e.g., the first side 102 and the second side 104, are respectively extended as a scribe seal extension 144 to form a sharp corner 146. The sharp corner 146 is also referred to as one of the four virtual corners of the die 110. Thus, the semiconductor device 100 includes four scribe seal extensions forming four sharp corners. The scribe seal extension 144 redundantly encloses a corresponding one of the sloped corners 142, thereby providing improved protection to the die 110. Specifically, the scribe seal extension 144 and each one of the sloped corners 142 provides two walls of metal to protect the die 110 from a stress induced defect originating at or near the physical die corners 130. The metal wall of the scribe seal extension 144 is advantageously extended very close to the physical die corners 130, where the induced stress is the highest. Additional detail of the metal walls formed by the scribe seal structure is described with reference to FIG. 1C.

Each one of the scribe seal extension 144 encloses a triangular area 148. In the depicted embodiment, an electrical test point 170 is located in the triangular area 148 enclosed within the scribe seal extension 144 and a corresponding one of the sloped corners 142. The electrical test point 170 provides input and output access to the die 110 for performing tests.

In an embodiment, the scribe seal 140 and the scribe seal extension 144 have equal widths. Depending on factors such as the size of the die 110, the technology used, and the particular application, the width may be configured to be approximately 10 microns. A size of the die 110 is unaffected by the inclusion of the first scribe seal 140, the second scribe seal 150, and the third scribe seal 160. That is, the improved seal structure provides increased protection to the die 110 without increasing the die size.

In an embodiment, the sharp corner 146 of the scribe seal extension 144 is located within a configurable distance of physical die corners 130. The configurable distance may depend of various factors such as saw street width, saw kerf, and similar others. The configurable distance, which may be made as small as practical, advantageously limits the dimensions of defects such as the cracks, blisters or delamination. By limiting the distance between the physical die corners 130 and the second scribe seal 150, the leverage action of the stress forces is also limited. Thus, the improved seal structure is able to better absorb the energy associated with crack propagation.

FIG. 1B illustrates a simplified and schematic top view of the semiconductor device 100 described with reference to FIG. 1A having an optional enclosed scribe seal 150, according to an embodiment. In the depicted embodiment, the enclosed scribe seal 150, which may be provided as an option, is an independent scribe structure that is enclosed within the scribe seal extension 144 and a corresponding one of the sloped corners 142 of the scribe seal 140. Thus, the semiconductor device 100 includes four enclosed scribe seals.

Similar to the scribe seal extension 144, the enclosed scribe seal 150 has a sharp corner 152 formed by two sides, each of which is respectively parallel to a corresponding side of the scribe seal 140. The enclosed scribe seal 150 encloses an area 158 resembling a right angled triangle. In the depicted embodiment, the electrical test point 170 is located in the area 158.

In an embodiment, the scribe seal 140, the scribe seal extension 144, and the enclosed scribe seal 150 have equal widths. Depending on factors such as the size of the die 110, the technology used, and the particular application, the width may be configured to be approximately 10 microns. In an embodiment, spacing between adjacent ones of the scribe seal 140, the scribe seal extension 144, and the enclosed scribe seal 150 is uniform. A size of the die 110 is unaffected by the inclusion of the scribe seal 140, the scribe seal extension 144, and the enclosed scribe seal 150. That is, the improved seal structure provides increased protection to the die 110 without increasing the die size.

As described earlier, the improved scribe seal structure provided by the scribe seal 140, the scribe seal extension 144, and the enclosed scribe seal 150 includes multiple metal walls, which act as protective barriers against potential damage caused by stress induced defects, especially defects which originate at or near the physical corners 130 of the die 110. In the depicted embodiment, the improved scribe seal structure provides up to four walls of metal to protect the die 210 from a stress induced defect originating at or near the physical die corners 230. The scribe seal extension 144 is advantageously extended very close to the physical die corners 230, where the induced stress is the highest.

FIG. 1C illustrates a simplified and schematic cross sectional view of the semiconductor device 100 described with reference to FIG. 1B having the enclosed scribe seal, according to an embodiment. Each one of the scribe seal extension 140 and the enclosed scribe seal 150 include a BEOL stack that includes a plurality of metal layers 180 formed on a substrate 182, and a plurality of insulating layers 184 disposed between adjacent ones of the plurality of metal layers 180. The plurality of metal layers 180 are connected by vias 186 made in the plurality of insulating layers 184.

The plurality of metal layers 180 and the vias 186 form one or more metal walls, which provides mechanical strength and enable the scribe seal structure to disperse the energy associated with defect formation such as crack propagation or delamination. Each metal wall also provides an enclosed protective barrier for the die 110 against infiltration by contaminants such as moisture and chemical impurities. The improved scribe seals are fabricated in the same manner as the back end of line (BEOL) stack of a semiconductor device. Thus, the semiconductor device 100 having the improved scribe seal structure is advantageously manufacturable by using existing materials and processes to improve reliability and reduce costs. In the depicted embodiment, the enclosed scribe seal 150 is a mirror image of the scribe seal extension 140.

FIG. 1D illustrates a simplified and schematic top view of a semiconductor device 101 having a detached scribe seal 160, according to an embodiment. In the depicted embodiment, the semiconductor device 101 is the same as the semiconductor device 100 described with reference to FIGS. 1A, 1B and 1C except for the detached scribe seal 160. The detached scribe seal 160 is different than the scribe seal extension 144 since the detached scribe seal 160 is an independent scribe seal structure that is not mechanically or electrically coupled to the scribe seal 140. The detached scribe seal 160 is similar to the scribe seal extension 144 since both have respective sharp corners 162 and 146.

Similar to the scribe seal extension 144, the detached scribe seal 160 has the sharp corner 162 formed by two sides, each of which is respectively aligned with a corresponding side of the scribe seal 140 but is separated by a gap 164. That is, the detached scribe seal 160 is separated from the scribe seal 140 by the gap 164. The gap 164 advantageously isolates the die 110 by eliminating or at least limiting the amount of stress energy transferred to the scribe seal 140. Specifically, the presence of the gap 164 limits or contains the stress energy originating in the physical die corners 230 to be dissipated within the detached scribe seal 160. In the depicted embodiment, the detached scribe seal 160 and a corresponding one of the sloped corners 142 of the scribe seal 140 partially enclose an area 168 resembling a right angled triangle. In the depicted embodiment, the electrical test point 170 is located in the area 168. In the depicted embodiment, the detached scribe seal 160 may include an optional closed third side 166 that is parallel to a corresponding one of the sloped corners 142 of the scribe seal 140 to enclose the area 168 resembling a right angled triangle.

Referring to FIGS. 1A, 1B, 1C, and 1D, it is understood that although not shown, any one of the scribe seal structures such as the scribe seal 140, the scribe seal extension 144, and the detached scribe seal 150 or a combination thereof may be included in various configurations and combinations, e.g., in a redundant configuration, to further improve the protection of the die 110. For example, as described earlier, a redundant scribe seal may be formed between the scribe seal 140 and the die 110. As another example, two detached scribe seals each in the form of a right angled triangle may be formed in the virtual die corners to protect the die 110, e.g., an outer triangular detached scribe seal enclosing an inner triangular detached scribe seal.

FIG. 2 is a flow chart illustrating a method for fabricating a semiconductor device having an improved scribe seal structure, according to an embodiment. In a particular embodiment, FIG. 2 illustrates the process for fabricating the semiconductor device 100 described with reference to FIGS. 1A, 1B, 1C, and 1D. At step 210, a scribe seal is formed to surround a die having sloped corners. The scribe seal has sides to form sloped corners that match the sloped corners of the die. At step 220, the sides of the scribe seal are extended to form a scribe seal extension in each virtual die corner. The scribe seal extension redundantly encloses a corresponding one of the sloped corners of the scribe seal. At step 230, as an option, the scribe seal is separated from the scribe seal extension by removing an end portion of the scribe seal extension to generate a gap at each end.

Various steps described above may be added, omitted, combined, altered, or performed in different orders. For example, step 240 may be added to place an electrical test point in the triangular area enclosed within the third scribe seal, the electrical test point being operable to test the die.

Several advantages are achieved by the method according to the illustrative embodiments presented herein. The embodiments advantageously provide an improved scribe seal structure surrounding the die. The improved scribe seal structure includes multiple metal walls which act as protective barriers against potential damage caused by stress induced defects, especially defects which originate at or near the physical corners of the die. The scribe seal structure is advantageously extended very close to the physical corners, where the induced stress is the highest. This limits the length of the cracks, and hence limits the leverage action of the stress forces, before they encounter a metal wall. The semiconductor device having the improved scribe seal structure is advantageously manufacturable by using existing materials and processes, thereby improving reliability and reducing costs. The die size is unaffected by the improved scribe seal structure. That is, the improved seal structure provides improved protection without reducing the die size.

Although illustrative embodiments have been shown and described, a wide range of modification, change and substitution is contemplated in the foregoing disclosure and in some instances, some features of the embodiments may be employed without a corresponding use of other features. Those of ordinary skill in the art will appreciate that the hardware and methods illustrated herein may vary depending on the implementation. For example, while certain aspects of the present disclosure have been described in the context of sloped corners, those of ordinary skill in the art will appreciate that the processes disclosed are capable of being used for assembly of semiconductor devices having corners of different shapes or geometries. As another example, while certain aspects of the present disclosure have been described in the context of scribe seals that are attached to the scribe seals of the die, those of ordinary skill in the art will appreciate that the processes disclosed are capable of being used for assembly of semiconductor devices having detached scribe seals. As yet another example, while certain aspects of the present disclosure have been described in the context of single (non-redundant) scribe seals for protecting the die, those of ordinary skill in the art will appreciate that any one of the scribe seal structures is capable of being duplicated to provide redundant protection for the die.

The methods and devices described herein provide for an adaptable implementation. Although certain embodiments have been described using specific examples, it will be apparent to those skilled in the art that the invention is not limited to these few examples. The benefits, advantages, solutions to problems, and any element(s) that may cause any benefit, advantage, or solution to occur or become more pronounced are not to be construed as a critical, required, or an essential feature or element of the present disclosure.

The above disclosed subject matter is to be considered illustrative, and not restrictive, and the appended claims are intended to cover all such modifications, enhancements, and other embodiments, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A semiconductor device comprising:
a die having sloped corners;
a scribe seal formed around the perimeter of the die, the scribe seal having sides to form sloped corners that match the sloped corners of the die; and
a scribe seal extension having sharp corners to redundantly enclose the sloped corners of the scribe seal, the sides of the scribe seal having a perpendicular orientation towards one another being extended to form the sharp corners.

2. The semiconductor device of claim 1 further comprising:
an enclosed scribe seal enclosed between the sharp corners of the scribe seal extension and the sloped corners of the scribe seal, the enclosed scribe seal enclosing an area resembling a right angled triangle.

3. The semiconductor device of claim 2 further comprising:
an electrical test point located in the area, the electrical test point being operable to test the die.

4. The semiconductor device of claim 2, wherein the scribe seal, the scribe seal extension, and the enclosed scribe seal have equal widths.

5. The semiconductor device of claim 2, wherein the scribe seal, the scribe seal extension, and the enclosed scribe seal collectively provide four walls of metal to protect the die from a stress induced defect originating near a physical die corner of the die.

6. The semiconductor device of claim 2, wherein spacing between adjacent ones of the scribe seal extension and the enclosed scribe seal is uniform.

7. The semiconductor device of claim 2, wherein a cross section of scribe seal extension is a mirror image of a cross section of the enclosed scribe seal.

8. The semiconductor device of claim 1, wherein the sloped corners of the die are aligned at a 45 degree angle relative to the sides of the die.

9. The semiconductor device of claim 1, wherein the sharp corners of the scribe seal extension form a 90 degree angle.

10. The semiconductor device of claim 1, wherein the sharp corners of the scribe seal extension are located within a configurable distance of physical die corners of the die, the physical die corners being formed when the die is singulated.

11. The semiconductor device of claim 10, wherein stress induced defects originating near the physical die corners are limited to be formed within the configurable distance, the configurable distance being a function of a street width on a wafer containing the die.

12. The semiconductor device of claim 1, wherein the die is one of a microprocessor, a digital signal processor, a radio frequency chip, a memory, a microcontroller, and a system-on-a-chip, or a combination thereof.

13. The semiconductor device of claim 1, wherein the scribe seal and the scribe seal extension each have a width of approximtaely 10 microns.

14. A method for fabricating a semiconductor device having a redundant scribe seal, the method comprising:
surrounding a die having sloped corners with a scribe seal, the scribe seal having sides to form sloped corners that match the sloped corners of the die; and
extending the sides of the scribe seal to form a scribe seal extension in each virtual die corner, wherein the scribe seal extension redundantly encloses a corresponding one of the sloped corners of the scribe seal.

15. The method of claim 14 further comprising:
separating the scribe seal from the scribe seal extension by removing an end portion of the scribe seal extension to generate a gap at each end.

15. The method of claim 14 further comprising:
placing an electrical test point in an area enclosed within the third scribe seal, the electrical test point being operable to test the die.

16. The method of claim 14, wherein the scribe seal and the scribe seal extension have equal widths.

17. A scribe seal structure to protect a die, the die having a rectangular shape with sloped corners, the scribe seal structure comprising:
a scribe seal formed along the perimeter of the die to surround the die, the scribe seal having sloped corners to match the sloped corners of the die; and
a detached scribe seal having two sides that form a sharp corner, the detached scribe seal being separated from the scribe seal by a gap, wherein each one of the two sides of the detached scribe seal is aligned with a corresponding side of the scribe seal.

18. The scribe seal structure of claim 17 further comprising:
a second detached scribe seal disposed between the detached scribe seal and the scribe seal, the second detached scribe seal having sharp corners to match the sharp corners of the detached scribe seal, wherein the second detached scribe seal is separated from the scribe seal by the gap.

19. The scribe seal structure of claim 18, wherein the scribe seal, the detached scribe seal, and the second detached scribe seal have equal widths.

20. The scribe seal structure of claim 17, wherein the gap protects the die from a stress induced defect originating near a physical die corner of the die by containing the stress within the detached scribe seal.
